(19) United States
(12) Patent Application Publication
(10) Pub. No.: US 2016/0079487 A1
(43) Pub. Date: Mar. 17, 2016

(54) SEMICONDUCTOR LIGHT-EMITTING DEVICE

(71) Applicant: KABUSHIKI KAISHA TOSHIBA, Tokyo (JP)

(72) Inventor: Toshihiro KUROKI, Nonoichi Ishikawa (JP)

(21) Appl. No.: 14/634,884

(22) Filed: Mar. 1, 2015

(30) Foreign Application Priority Data
Sep. 16, 2014 (JP) 2014-187916

(51) Int. Cl. H01L 33/50; H01L 33/40; H01L 33/60; H01L 33/54

(52) U.S. Cl. CPC H01L 33/507; H01L 33/54; H01L 33/405; H01L 33/60

(57) ABSTRACT

A semiconductor light-emitting device includes a package that includes a bottom surface and a first side section provided surround the bottom surface, a chip that includes a supporting substrate and a light-emitting section provided on the supporting substrate and is disposed on the bottom surface and spaced from the first side section, and a phosphor layer that is on the chip in a region above the bottom surface.

### CROSS-REFERENCE TO RELATED APPLICATION

This application is based upon and claims the benefit of priority from Japanese Patent Application No. 2014-187916, filed Sep. 16, 2014, the entire contents of which are incorporated herein by reference.

### FIELD

Embodiments described herein relate generally to a semiconductor light-emitting device.

### BACKGROUND

An LED chip in which a low cost silicon substrate is used as a supporting substrate is advantageously manufactured in large sizes, but there is a concern that light absorption of the silicon substrate causes the light extracting efficiency of a packaged LED to be low.

### DESCRIPTION OF THE DRAWINGS

FIG. 1A is a cross-sectional view schematically illustrating a semiconductor light-emitting device according to an embodiment and FIG. 1B is a plan view schematically illustrating the semiconductor light-emitting device according to the embodiment.

FIG. 2 is a cross-sectional view schematically illustrating a chip according to the embodiment.

FIGS. 3A and 3B are cross-sectional views schematically illustrating semiconductor light-emitting devices according to other embodiments, respectively.

### DETAILED DESCRIPTION

An example embodiment provides is a semiconductor light-emitting device having improved light extraction efficiency.

According to one embodiment, a semiconductor light-emitting device comprises a resin package element having a first surface section that includes a first surface in a first plane. A first side section of the resin package element is surrounding a perimeter of the first surface. The first side section extends in a first direction that is orthogonal to the first plane and has a second surface that is spaced from the first surface in the first direction. A chip that includes a supporting substrate and a light-emitting section on the supporting substrate is disposed on the first surface section within the perimeter of the first surface and is spaced from the first side section. A phosphor layer is above the chip in the first direction, for example, the phosphor layer may be directly above and contacting the light-emitting section or other material may be between the phosphor layer and the light-emitting section.

Hereinafter, example embodiments will be described with reference to the drawings. In the drawings, s the same reference numerals are used to indicate substantially similar components.

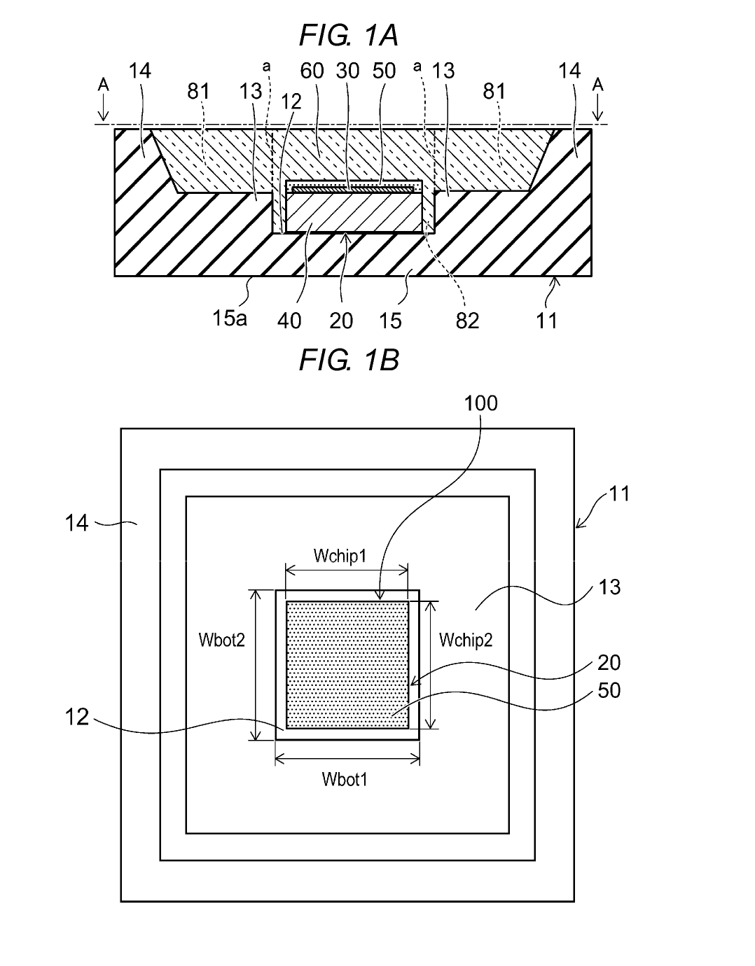

FIG. 1A is a cross-sectional view schematically illustrating a semiconductor light-emitting device according to an embodiment.

FIG. 1B is a plan view schematically illustrating the semiconductor light-emitting device according to the embodiment. FIG. 1B corresponds to a view when viewed from arrows A-A in FIG. 1A. A transparent resin 60 illustrated in FIG. 1A is omitted in FIG. 1B.

The semiconductor light-emitting device includes a package 11, a chip 20 accommodated in the package 11, a phosphor layer 50 provided on the chip 20, and the transparent resin 60 that covers the chip 20.

The package 11 includes a base section 15, a first side section (reflector) 13, and a second side section (outer circumferential wall) 14. The package 11 is a molded body formed of a resin, and thus, the base section 15, the second side section 14 and the first side section 13 are provided integrally to each other.

The base section 15 is in a plate shape having a rear surface 15a. The rear surface 15a can be mounted to a printed circuit board or the like. The second side section 14 and the first side section 13 protrude away from the base section 15. The second side section 14 forms a side outer surface of the package 11. The first side section 13 is provided within the side outer surfaces of the second side section 14.

A bottom surface 12 inside of the first side section 13. The first side section 13 continuously surrounds the periphery (outer perimeter) of the bottom surface 12. A step is formed between a top surface of the second side section 14 and a top surface of the first side section 13 and a step is formed between the top surface of the first side section 13 and the bottom section 12. The bottom surface 12 is formed on a side of base section 15 that is opposite to the rear surface 15a. An elevation of the top surface of the first side section 13 is greater than the elevation of the bottom surface 12 and an elevation of the top surface of the second side section 14 is greater than the elevation of the first side section 13. Here, the elevation represents an elevation measured from the rear surface 15a of the package 11 as a reference.

The chip 20 includes a supporting substrate 40 and a light-emitting section 30 provided on the supporting substrate 40. The supporting substrate 40 is a silicon substrate, for example. The silicon substrate makes it possible to suppress cost and thus to form a large supporting substrate.

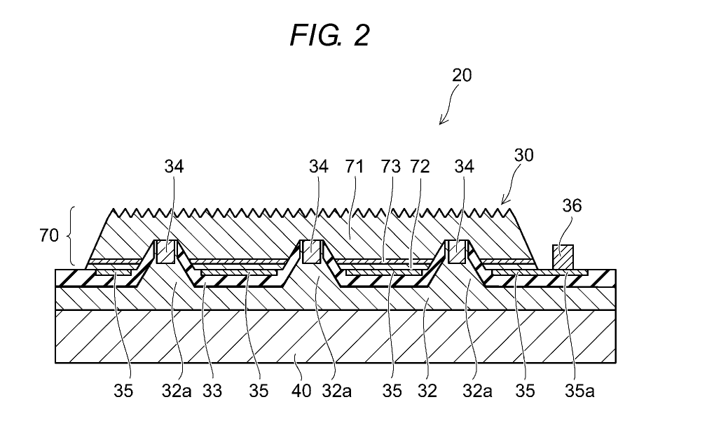

FIG. 2 is a cross-sectional view schematically illustrating the chip 20.

The light-emitting section 30 includes a semiconductor layer 70. The semiconductor layer 70 contains gallium nitride, for example. The semiconductor layer 70 includes a first layer 71, a second layer 72, and a light-emitting layer (active layer) 73 provided between the first layer 71 and the second layer 72.

The first layer 71 includes, for example, a base buffer layer and an n-type GaN layer. The second layer 72 includes, for example, a p-type GaN layer. The light-emitting layer 73 contains materials that emit light such as blue light, violet light, bluish-violet light, or ultra-violet light. A peak light-emission wavelength of the light-emitting layer 73 is, for example, in a range of 430 nm to 470 nm.

The first layer 71 has an uneven (rough) upper surface, as depicted in FIG. 2, so as to limit internal reflections. In the semiconductor layer 70, the first layer 71 includes a region which below the uneven upper surface and has a surface that is on a side opposite to the uneven upper surface. Below (e.g., in the downward page direction of FIG. 2) this region of the first layer 71 is adjacent to neither the second layer 72 nor the light-emitting layer 73. That is, in semiconductor layer 70, the second layer 72 and the light-emitting layer 73 are absent in a portion below the region of the first layer 71. A first electrode (n-side electrode) 34 is provided to be in contact with the first layer 71 in the region. A second electrode (p-side electrode) 35 is provided under the surface of the second layer 72.

A metal layer 32 is provided on a side opposite to the upper surface of the first layer 71. The metal layer 32 is connected to the first electrode 34. An insulation film(s) 33 is/are provided between the metal layer 32 and the second electrode 35. The insulation film(s) 33 is/are also provided between the first electrode 34 and the light-emitting layer 73, between the first electrode 34 and the second layer 72, between the metal layer 32 and the light-emitting layer 73, and between the metal layer 32 and the second layer 72.

A portion 35a of the second electrode 35 extends outwardly from the side surface of the semiconductor layer 70 and is provided on the insulation film 33. A connection pad (pad) 36 is provided on the portion 35a of the second electrode 35.

The metal layer 32 is provided on the supporting substrate 40, and the semiconductor layer 70 is provided over the metal layer 32 interposing the insulation film 33 therebetween. The second electrode 35 is provided between the second layer 72 of the semiconductor layer 70 and the insulation film 33.

A portion 32a of the metal layer 32 protrudes into the semiconductor layer 70 side. The first electrode 34 is provided between the portion 32a of the metal layer 32 and the first layer 71.

The semiconductor layer 70 is typically formed by epitaxial growth on a growth substrate (not illustrated). The growth substrate is, for example, a silicon substrate, a sapphire substrate, or a silicon carbide substrate. The first layer 71, the light-emitting layer 73, and the second layer 72 are also typically formed by the epitaxial growth on a growth substrate in that order. Then, portions of the second layer 72 and the light-emitting layer 73 are removed by reactive ion etching (RIE) using an etch mask (not illustrated) disposed thereon.

The first electrode (n-side electrode) 34 is provided within the portion of semiconductor layer 70 where the second layer 72 and the light-emitting layer 73 have been removed.

The second electrode (p-side electrode) 35 is provided on the surface (or a portion thereof) of the second layer 72.

The growth substrate is removed after the light-emitting section 30 that includes the semiconductor layer 70, the electrodes 34 and 35, the insulation film 33, and the metal layer 32 is adhered to the supporting substrate 40. The rear surface of the metal layer 32 is joined or bonded to the supporting substrate 40.

After the light-emitting section 30 is adhered to the supporting substrate 40 and the growth substrate is removed from the semiconductor layer 70, the front surface of the first layer 71 is formed to be uneven (roughened) so has to not be optically smooth.

As illustrated in FIGS. 1A and 1B, the phosphor layer 50 is provided on the chip 20.

The phosphor layer 50 contains a resin and a plurality of phosphors dispersed in the resin. The phosphor is excited by radiation light from the light-emitting layer 73 and radiates light having a different wavelength from the radiation light. The resin in which the plurality of phosphors is dispersed is transparent with respect to the radiation light from the light-emitting layer 73 and the radiation light from the phosphors. Here, “transparent” refers not only a case where the transmittance of light is 100%, but also to a case where a part of light is absorbed. The resin of the phosphor layer 50 can be a silicone resin, for example.

The phosphor layer 50 is laminated on the chip 20 within a region 100 on the bottom surface 12 of the package 11. The region 100 on the bottom surface 12 represents an inner side region from an edge of the bottom surface 12 (a boundary between the first side section 13 and the bottom surface 12) and from a line (virtual line) “a” that extends upward perpendicularly to the bottom surface 12. The phosphor layer 50 is not provided in a region that covers the top surface of the first side section 13 on the outer side from the extended line a.

That is, in the plan view in FIG. 1B, the phosphor layer 50 does not extend to the region which covers the top surface of the first side section 13, but is positioned within the region 100 surrounded by the first side section 13 in a box shape. The region 100 is a region where the chip 20 is disposed and the phosphor layer 50 is positioned within the region 100 which covers the chip 20. Even when the phosphor layer 50 slightly sticks out from the top surface of the supporting substrate 40, and covers a part of a side surface of the supporting substrate 40 which is continuous from the top surface, it is considered that the phosphor layer 50 is positioned within the region that covers the chip 20. The phosphor layer 50 covers the top surface and the side surfaces of the light-emitting section 30.

The supporting substrate 40 is thicker than the light-emitting section 30. The phosphor layer 50 is thinner than the chip 20.

The package 11 includes a first concave section 81 surrounded by the second side section 14. Further, a second concave section 82 surrounded by the first side section 13 is formed in the bottom of the first concave section 81 and the bottom surface 12 where the chip 20 is disposed is provided on the bottom of the second concave section 82. The transparent resin 60 is provided in the first concave section 81 and the second concave section 82 of the package 11.

The transparent resin 60 is transparent with respect to the radiation light of the light-emitting layer 73 and the radiation light of the phosphor. The transparent resin 60 is, for example, a silicon resin. The transparent resin 60 does not include any phosphor. A light-scattering material may be dispersed in the transparent resin 60.

The light radiated from the chip 20 and the phosphor on the chip 20 enters the transparent resin 60 in the first concave section 81 and may be reflected outward (upward page direction in FIG. 1A) by an inner wall of the second side section 14 having a slope such that the top surface of the second side section 14 and the inner wall form an obtuse angle such that it is possible to extract light from a wider region.

The transparent resin 60 covers the chip 20 and the phosphor layer 50. The transparent resin 60 is provided even between the first side section 13 and the chip 20.

The semiconductor light-emitting device according to the depicted example embodiment has a so-called “flat package” structure in which the top surface (interface with the air), from which the light is emitted to the outside of the package, is flat. A top surface 60a of the transparent resin 60 is not formed to have a convex lens shape, but is parallel to a plane direction of the supporting substrate 40 and is substantially a flat and non-lens-like surface.

The transparent resin 60 is supplied in the package 11, for example, in a state (state of liquid) of having fluidity, and then is cured. Curing shrinkage at this time causes the top surface 60a of the transparent resin 60 to be slightly indented in some cases. Such unintended deformation of a shape during manufacturing still means that the top surface 60a of the transparent resin 60 is substantially flat.

The semiconductor light-emitting device with the flat package structure improves mountability when the device is mounted on a circuit board or the like by using collector that vacuum adheres the flat top surface. In addition, the semiconductor light-emitting device with the flat package structure is small in size by having a short height thickness).

The second electrode 35 illustrated in FIG. 2 is electrically connected to an external circuit through a wire (not illustrated) which is bonded to the pad 36. The first electrode 34 is electrically connected to an external circuit through the metal layer 32 and the conductive supporting substrate (silicon substrate) 40.

A current is supplied to the light-emitting layer 73 through the first electrode 34 and the second electrode 35 such that the light-emitting layer 73 emits light. The light radiated from the light-emitting layer 73 is incident to the phosphor layer 50 and a part of the light causes the phosphor to be excited such that, for example, white light is obtained as mixed light of the light from the light-emitting layer 73 and the light from the phosphor.

An interface of the semiconductor layer 70 with the phosphor layer 50 is uneven (rough). Therefore, light-emission efficiency from the semiconductor layer 70 to the phosphor layer 50 is improved.

The chip 20 is mounted on the bottom surface 12 surrounded by the first side section 13 in the package 11 through bonding paste.

As illustrated in FIG. 1B, a first width Wbot 1 of the bottom surface 12 is slightly greater than a first width Wchip 1 of the chip 20. The first width Wbot 1 of the bottom surface 12 and the first width Wchip 1 of the chip 20 indicate widths in the same direction. A second width Wbot 2 in a direction orthogonal to the first width Wbot 1 of the bottom surface 12 is slightly greater than the second width Wchip 2 in a direction orthogonal to the first width Wchip 1 of the chip 20. The second width Wbot 2 of the bottom surface 12 and the second width Wchip 2 of the chip 20 indicate widths in the same direction. Accordingly, it is possible to mount the chip 20 on the bottom surface 12 without interfering with the first side section 13. A gap is formed between the inner wall of the first side section 13 and the side section of the chip 20.

The first side section 13 faces the side section of the chip 20 and continuously surrounds the periphery of the side section of the chip 20. A distance (size of the gap) between the side section of the chip 20 and the first side section 13 is less than the thickness of the chip 20. The side section of the chip 20 includes the side section of the supporting substrate 40.

If the transparent resin that seals the chip is formed in a convex lens shape, reflection on the interface between the transparent resin and the air is suppressed and thus, it is possible to improve the light-extracting efficiency to the outside (air).

In contrast, in the flat package structure, since the top surface 60a of the transparent resin 60 is substantially flat, the light is likely to be reflected on the interface between the top surface 60a of the transparent resin 60 and the air and to return to the chip 20 compared to the convex lens structure. Further, the silicon substrate of the supporting substrate 40 absorbs light.

The package 11 including the first side section 13 has reflectivity to the radiation light of light-emitting layer 73 and the radiation light of the phosphor. For example, the package 11 includes a silicone resin or an epoxy resin.

The first side section 13 having such light reflectivity comes closer to the side section of the chip 20, and thereby light which returns toward the side section of the chip 20 is blocked by the first side section 13 such that the light is unlikely to be incident to the side section of the chip 20. As a result, loss of light by being absorbed to the supporting substrate 40 (silicon substrate) is decreased, making it possible to improve the light-extracting efficiency to the outside (air).

The smaller the gap between the first side section 13 and the chip 20, the less the light is incident to the side section of the chip 20. The gap is appropriately set in a range in which workability of mounting of the chip within the package 11 is not lost.

In addition, it is desired that the elevation of the top surface of the first side section 13 be half to twice the thickness of the chip 20 when taking into account the prevention of the returning light from being incident to the chip side section and the workability of mounting of the chip. In an example illustrated in FIGS. 1A and 1B, the elevation of the top surface of the first side section 13 is substantially the same as the thickness of the chip 20.

In a structure where the phosphor layer is provided all across the package, since the phosphor is dispersed in a region closer to the outer side than the side surface of the chip, the radiation light of the phosphor which is incident to the side surface of the silicon substrate becomes great.

In contrast, according to the embodiment, because the phosphor layer 50 is controlled to be positioned within a range in which the phosphor layer 50 covers the chip 20 within a region over the bottom surface 12, it is possible to decrease the radiation light from the phosphor toward the side section of the supporting substrate 40. Accordingly, the loss of the light by being absorbed to the supporting substrate 40 is decreased making it possible to improve the extraction efficiency.

The light toward the top surface side of the chip 20 from the phosphor is caused to be reflected upward by the electrode of the light-emitting section 30 and it is possible to extract the light to the outside.

For example, the first electrode (n-side electrode) 34 of the light-emitting section 30 illustrated in FIG. 2 contains an aluminum (Al) film and the second electrode (p-side electrode) 35 contains a silver (Ag) film. Aluminum and silver have high reflectivity to the light radiated from the light-emitting layer 73 and the light radiated from the phosphor.

In addition, according to the embodiment illustrated in FIGS. 1A and 1B, the phosphor layer 50 is provided as a thin film on the chip 20 and the phosphor layer 50 is thinner than the chip 20 in thickness. Accordingly, the phosphor is controlled to be positioned in a region closer to the top surface of the chip 20 and the radiation light from the phosphor is unlikely to be incident to the side surface of the supporting substrate 40.

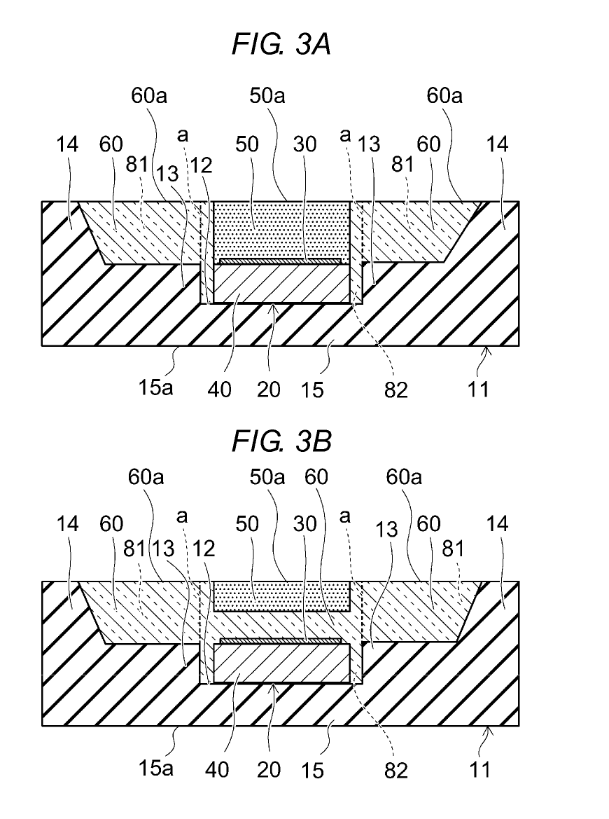

FIG. 3A is a cross-sectional view schematically illustrating a semiconductor light-emitting device according to another embodiment.

According to the embodiment illustrated in FIG. 3A, the phosphor layer 50 is provided in the region over the bottom surface 12 from the top surface of the chip 20 to the top surface of the package 11. A top surface 50a of the phosphor layer 50 is not covered by the transparent resin 60, but is exposed to the outside of the package. The top surface 50a of the phosphor layer 50 and the top surface 60a of the transparent resin 60 are continuous with each other and are substantially flat.

According to the embodiment in FIG. 3A, since the phosphor layer 50 is controlled to be positioned within a range that covers the chip 20 in a region over the bottom surface 12, the radiation light of the phosphor which is incident to the side section of the supporting substrate 40 may be decreased.

FIG. 3B is a cross-sectional view schematically illustrating a semiconductor light-emitting device according to still another embodiment.

According to the embodiment in FIG. 3B, the phosphor layer 50 is controlled to be positioned within a range that covers the chip 20 in a region over the bottom surface 12, and to be separated from the chip 20 on the top surface side of the package 11. The top surface 50a of the phosphor layer 50 is not covered by the transparent resin 60, but is exposed to the outside of the package. The top surface 50a of the phosphor layer 50 and the top surface 60a of the transparent resin 60 are continuous with each other and are substantially flat.

A part of the transparent resin 60 is provided between the phosphor layer 50 and the chip 20. For example, resin having a refractive index less than that of the resin of the phosphor layer 50 is selected as the transparent resin 60 between the phosphor layer 50 and the chip 20, making it possible to suppress reflection of the light of the light-emitting section 30 in the interface between the transparent resin 60 and the phosphor layer 50.

That is, the light (for example, blue light) from the light-emitting section 30 is not incident to the phosphor layer 50, but spreads in the transverse direction of the transparent resin 60 and is extracted to the outside, and thereby, it is possible to suppress color breakup.

A package structure may be employed in which the step between the top surface of the first side section 13 of the package 11 and the top surface of the second side section 14 is not formed, but the top surface of the first side section 13 extends upward to the same elevation as the top surface of the second side section 14. In this case, it is possible to decrease the package in size.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device, comprising:
a resin package element that includes a first surface section including a first surface in a first plane and a first side section surrounding a perimeter of the first surface, the first side section extending in a first direction orthogonal to the first plane and having a second surface spaced from the first surface in the first direction;
a chip that includes a supporting substrate and a light-emitting section on the supporting substrate, the chip being disposed on the first surface section within the perimeter of the first surface; and
a phosphor layer above the chip in the first direction.

2. The semiconductor light-emitting device according to claim 1, further comprising a transparent resin on the chip and having a second surface in a second plane parallel to the first plane.

3. The semiconductor light-emitting device according to claim 2, wherein a third surface of the phosphor layer is in the second plane such that the phosphor layer does not cover the third surface.

4. The semiconductor light-emitting device according to claim 3, wherein a portion of the transparent resin is between the chip and the phosphor layer.

5. The semiconductor light-emitting device according to claim 2, wherein a portion of the transparent resin is between the chip and the phosphor layer.

6. The semiconductor light-emitting device according to claim 1, wherein a distance from a side surface of the chip to the first side section in a second direction parallel to the first plane is less than a thickness of the chip along the second direction.

7. The semiconductor light-emitting device according to claim 1, wherein the light-emitting section includes:
a semiconductor layer that includes a light-emitting layer; and
an electrode provided on the semiconductor layer.

8. The semiconductor light-emitting device according to claim 7, wherein the electrode comprises silver or aluminum.

9. The semiconductor light-emitting device according to claim 1, wherein the phosphor layer has a thickness along the first direction that is less than the thickness of the chip.

10. The device according to claim 1, wherein the supporting substrate is a silicon substrate.

11. A light emitting device, comprising:
a package including:
a base section including a first surface,
a first side section surrounding a perimeter of the first surface by a first side section, and
a second side section that forms side surfaces of the package;
a chip disposed in the package on the first surface, within the perimeter, and including a supporting substrate and a light emitting section on the supporting substrate;
a phosphor layer including a resin material containing a plurality of phosphors dispersed therein, the phosphor being excited by light from the light emitting section; and
a transparent resin between the first side section and the chip.

12. The light emitting device according to claim 11, wherein light emitted by the phosphor has a different wavelength from light emitted by the light emitting section.

13. The light emitting device according to claim 11, wherein light from the light emitting section excites the phosphor layer and combines with the light from the phosphor layer to produce white light.

14. The light emitting device according to claim 11, wherein a gap between the chip and the first side section is in distance less than a thickness of the chip from the first surface.

15. The light emitting device according to claim 11, wherein the second side section has an inner wall with a slope such that a top surface of the second side section and the inner wall form an obtuse angle, the inner wall being reflective of light emitted by the light-emitting layer or the phosphor.

16. The light emitting device according to claim 11, wherein the first side section has a second surface parallel to the first surface and the second side section has a third surface parallel to the first surface, and the second and third surfaces are at different respective heights above the first surface.

17. The light emitting device according to claim 11, wherein the phosphor layer has a thickness that is less than a thickness of the chip.

18. The light emitting device according to claim 11, wherein the transparent layer includes a portion between the chip and the phosphor layer and has a refractive index that is less than a refractive index of the resin material of the phosphor layer.

19. A light emitting device, comprising:
a light emitting element disposed on a substrate;
a resin package including a first surface and first concave section surrounding a perimeter of the first surface, the first concave section extending in a first direction orthogonal to the first surface, the resin package element being reflective of light emitting by the light emitting element, the substrate being disposed on the first surface, and the light emitting element being within the perimeter of the first surface and not contacting the first concave section;
phosphor layer including a phosphor excited by light emitted by the light emitting layer and being above the first surface in the first direction; and
a transparent resin without phosphors being between the light emitting element and the first concave section in a second direction parallel to the first surface.

20. The light emitting device of claim 19, wherein the transparent layer is between the light emitting element and the phosphor layer along the first direction.
